(19) United States
(12) Patent Application Publication
(10) Pub. No.: US 2025/0189560 A1
(43) Pub. Date: Jun. 12, 2025

(54) ANODIZED FILM STRUCTURE AND INSPECTION DEVICE COMPRISING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Shin Goo KANG, Gyeonggi-do (KR)

(73) Assignee: POINT ENGINEERING CO., LTD., Chungcheongnam-do (KR)

(21) Appl. No.: 18/845,428

(22) PCT Filed: Mar. 6, 2023
(86) PCT No.: PCT/KR2023/003003

§ 371 Date: Sep. 9, 2024

(30) Foreign Application Priority Data
Mar. 11, 2022 (KR) 10-2022-0030764

(51) Int. Cl. G01R 1/073; G01R 1/30

(52) U.S. Cl. CPC G01R 1/0735; G01R 1/30

(57) ABSTRACT

Proposed are an anodized film structure which improves the mechanical and/or electrical characteristics by protecting perforated holes with a protective layer, and an inspection device. In the anodized film structure, parylene-type protective layer is formed with a uniform thickness on an inner wall of each of the perforated holes and a surface of the body made of an anodized film material. Micro-trenches are defined by peaks and valleys repeatedly arranged and formed on the inner wall of each of the perforated holes, and the protective layer covers the entire micro-trenches. In addition, a metal layer is provided on a surface of the body and between the protective layer and the inner wall of each of the perforated holes.

### CROSS-REFERENCE TO RELATED APPLICATION

This application is a 371 of international application of PCT application serial no. PCT/KR2023/003003 filed on Mar. 6, 2023 which claims the priority benefit of Korea application no. 10-2022-0030764 filed on Mar. 11, 2022. The entirety of each of the above mentioned patent applications is hereby incorporated by reference herein and made a part of this specification.

### TECHNICAL FIELD

The present disclosure relates to an anodized film structure and an inspection device including the same.

### BACKGROUND ART

An anodized film experiences little thermal deformation under a high-temperature atmosphere and has electrically insulating characteristics. Accordingly, research is being conducted to utilize these physical and/or electrical characteristics of the anodized film in various fields.

A semiconductor field is the field where the anodized film is used. The anodized film may be provided in an inspection device for inspecting an inspection target (for example, a semiconductor wafer or a semiconductor package).

At this time, the anodized film acts as a supporter of electrically conductive contact pins.

However, when perforated holes that penetrate the anodized film from top to bottom are formed, and the electrically conductive contact pins are inserted into the inner walls of the perforated holes, particles are generated from the inner walls of the perforated holes.

The particles generated on the inner walls of the perforated holes fall, leading to inspection errors or durability deterioration of the anodized film.

Therefore, using the anodized film as a structure with the perforated holes formed therein is necessary to improve the perforated holes.

### RELATED ART DOCUMENT

### Patent Document

(Patent Document 1) Korean Patent Application Publication No. 10-2020-0104061

### DISCLOSURE

### Technical Problem

To solve the problems, an objective of the present disclosure is to improve the mechanical characteristics of the inner walls of perforated holes by protecting the inner walls of the perforated holes through protective layers and minimizing particle generation caused by external forces on the inner walls of the perforated holes.

### Technical Solution

To solve the problems and achieve the objective, an anodized film structure according to one feature of the present disclosure includes a body made of an anodized film material; perforated holes provided in the body; and a protective layer provided on an inner wall of each of the perforated holes.

In addition, the protective layer is provided on the inner wall of each of the perforated holes and a surface of the body. The protective layer is evenly formed with a uniform thickness on the inner wall of each of the perforated holes and the surface of the body.

In addition, the protective layer is in a parylene form.

In addition, a metal layer is interposed between the inner wall of the perforated hole and the protective layer.

In addition, a plurality of the bodies is provided and stacked with a bonding layer provided between each of the bodies.

In addition, a metal layer is provided on a surface of the body, and the metal layer is interposed between the protective layer and the inner wall of the perforated hole.

In addition, a plurality of the perforated holes is provided. In at least some of the plurality of the perforated holes, the protective layer covers the metal layer so that the metal layer is not exposed, but in the remaining perforated holes, the metal layer is exposed.

In addition, the inner wall of the perforated holes is provided with micro-trenches defined by peaks and valleys repeatedly arranged in a circumferential direction of the perforated holes. The protective layers entirely cover the micro-trenches.

An inspection device according to another feature of the present disclosure includes an anodized film structure including bodies made of an anodized film material, perforated holes provided in the bodies, and protective layers provided on inner walls of the perforated holes; electrically conductive contact pins inserted into the perforated holes; and a circuit unit connected to the electrically conductive contact pins.

### Advantageous Effects

The present disclosure provides an anodized film structure that improves the mechanical and/or electrical characteristics of the inner walls of the perforated holes by protecting the inner walls of the perforated holes through protective layers and an inspection device including the same.

### DESCRIPTION OF DRAWINGS

FIG. 1 shows a plan view illustrating an anodized film structure according to a first preferred embodiment of the present disclosure;

FIG. 2 shows a view illustrating a plane cut along a line A-A′ of FIG. 1;

FIG. 3 shows a cross-sectional view illustrating a body made of an anodized film material according to another preferred embodiment of the present disclosure;

FIG. 4 shows a diagram illustrating the forming of a patternable material film on a first surface of the body made of an anodized film material and then patterning the patternable material film to form opening regions according to a further preferred embodiment of the present disclosure;

FIG. 5 shows a diagram illustrating the forming of perforated holes by removing the body made of the anodized film material in the opening regions using an etchant according to a yet further preferred embodiment of the present disclosure;

FIG. 6 shows a plan view illustrating the body made of the anodized film material with the perforated holes formed according to a still yet further preferred embodiment of the present disclosure;

FIG. 7 shows a diagram illustrating the formation of a protective layer in each of the perforated holes according to a still yet preferred embodiment of the present disclosure;

FIG. 8 shows a state in which insertion members are inserted into the anodized film structure according to the first preferred embodiment of the present disclosure;

FIG. 9 shows a state in which insertion members are inserted into the anodized film structure according to the second preferred embodiment of the present disclosure;

FIGS. 10A to 10H sequentially show a method of manufacturing an anodized film structure according to the second preferred embodiment of the present disclosure;

FIG. 11 shows a state in which insertion members are inserted into the anodized film structure according to the third preferred embodiment of the present disclosure;

FIG. 12 shows a diagram showing a state in which the first insertion member and the second insertion member are inserted into the anodized film structure according to the fourth preferred embodiment of the present disclosure;

FIG. 13 shows a diagram illustrating that an inspection device is a probe card according to a still yet further preferred embodiment of the present disclosure; and

FIG. 14 shows a diagram showing that the inspection device is a test socket according to a still yet further preferred embodiment of the present disclosure.

### MODE FOR DISCLOSURE

The following merely illustrates the principles of the present disclosure. Therefore, those skilled in the art will be able to implement the principles of the present disclosure, even when not explicitly explained or shown herein. In addition, those skilled in the art will be able to invent various devices included in the concept and scope of the present disclosure. In addition, all conditional terms and examples listed herein are, in principle, expressly intended solely for the purpose of ensuring that the inventive concept is understood. All the conditional terms and embodiments listed herein should be understood as not limiting to the specifically listed embodiments and conditions.

The purpose, features, and advantages will become clearer through the following detailed description in conjunction with the attached drawings. Accordingly, those skilled in the art to which the present disclosure pertains will be able to easily implement the technical idea of the present disclosure.

The embodiments described herein will be explained with reference to cross-sectional views and/or perspective views, which are ideal illustrations of the present disclosure. The thicknesses of films and regions shown in these drawings are exaggerated for an effective explanation of technical content. Thus, the form of the illustration may be modified depending on manufacturing techniques and/or tolerance. Accordingly, the embodiments of the present disclosure are not limited to the specific form shown but also include changes in form produced according to the manufacturing process. Technical terms used in this specification are merely used to describe specific embodiments and are not intended to limit the present disclosure. Singular expressions include plural expressions unless the context clearly dictates otherwise. In this specification, terms such as “include” or “comprise” are intended to indicate the presence of features, numbers, steps, operations, components, parts, or combinations thereof described in this specification. The terms should be understood as not precluding the presence or addition of one or more other features, numbers, steps, operations, components, parts, or combinations thereof.

Hereinafter, preferred embodiments of the present disclosure will be described in detail with reference to the attached drawings. In describing various embodiments below, components that perform the same function will be given like names and reference numbers for convenience even when the embodiments are different. In addition, the configuration and operation already described in other embodiments will be omitted for convenience.

### First Embodiment

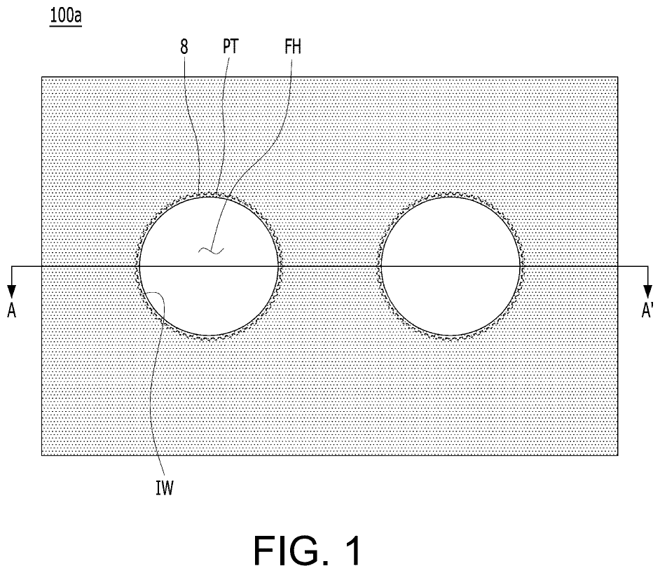

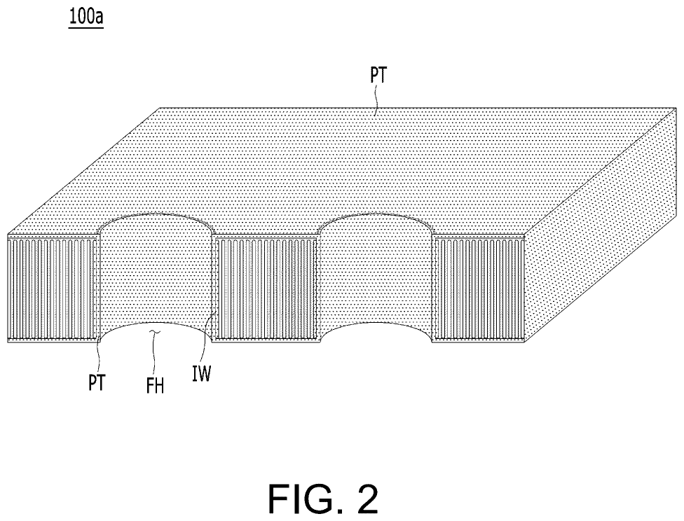

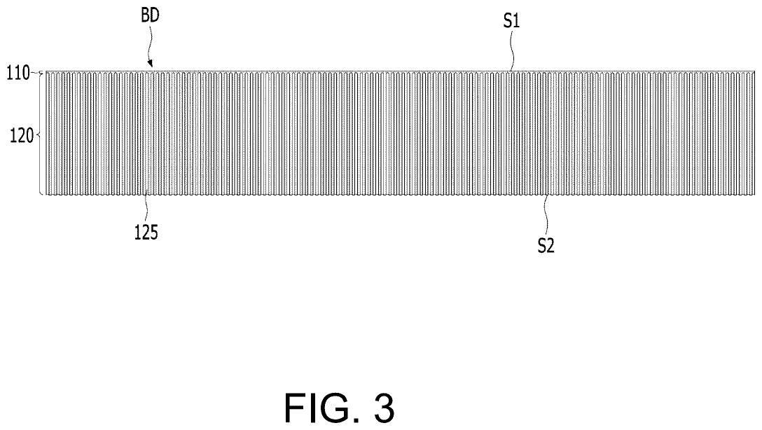

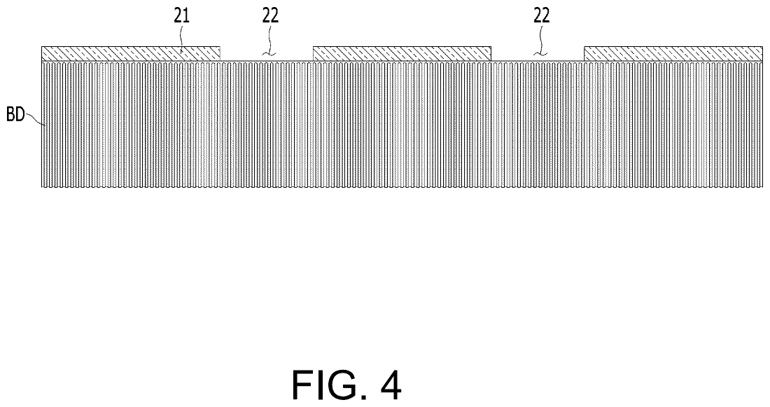

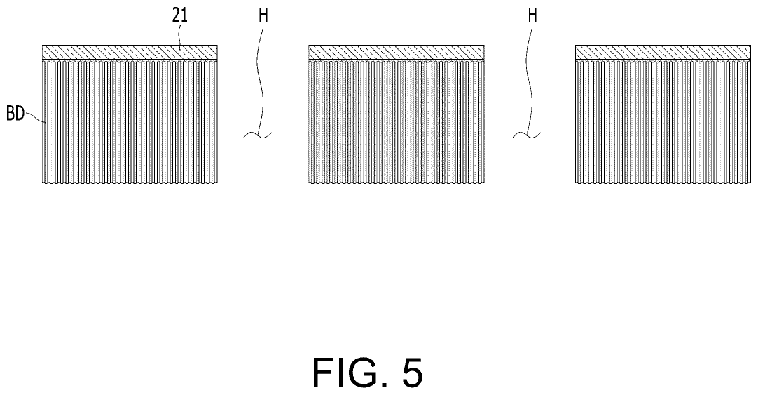

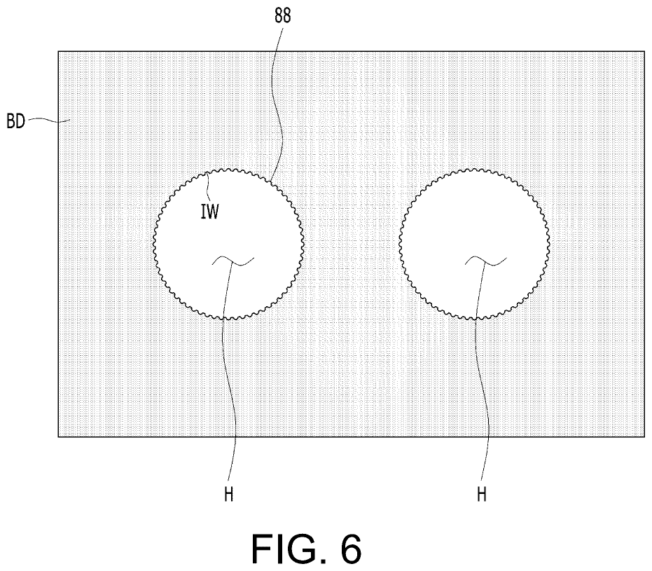

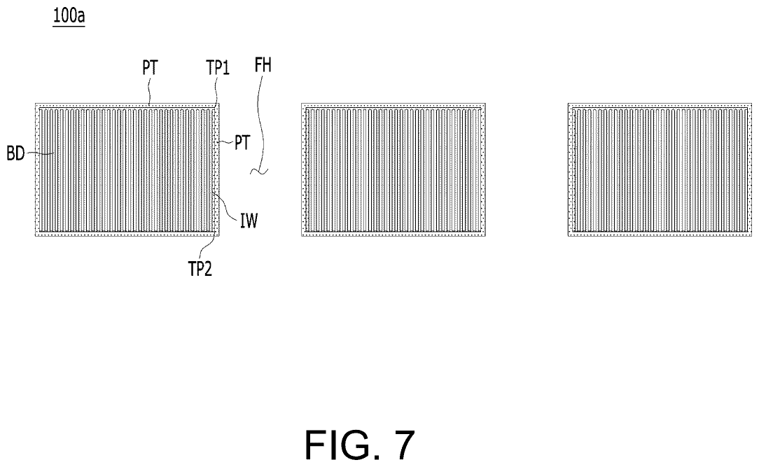

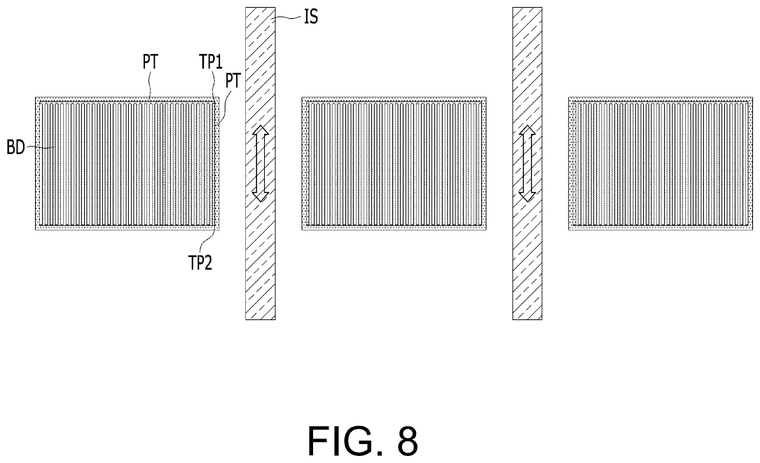

FIG. 1 shows a plan view illustrating an anodized film structure (hereinafter referred to as “the anodized film structure 100a of the first embodiment”) according to a first preferred embodiment of the present disclosure. FIG. 2 shows a view illustrating a plane cut along a line A-A′ of FIG. 1. FIG. 3 shows a diagram illustrating a body BD made of an anodized film material according to another preferred embodiment of the present disclosure. FIG. 4 shows a diagram illustrating the forming of a patternable material 21 film on a first surface S1 of the body BD made of an anodized film material and then patterning the patternable material 21 film to form opening regions 22 according to a further preferred embodiment of the present disclosure. FIG. 5 shows a diagram illustrating the forming of perforated holes FH by removing the body BD made of the anodized film material in the opening regions 22 using an etchant according to a yet further preferred embodiment of the present disclosure. FIG. 6 shows a plan view illustrating the body BD made of the anodized film material with the perforated holes FH formed according to a still yet further preferred embodiment of the present disclosure. FIG. 7 shows a diagram illustrating the formation of a protective layer PT in each of the perforated holes according to a still yet preferred embodiment of the present disclosure. FIG. 8 shows a state in which insertion members IS are inserted into the anodized film structure 100a according to the first preferred embodiment of the present disclosure.

The anodized film structure 100a according to the first embodiment includes a body BD made of an anodized film material, perforated holes FH provided in the body BD, and a protective layer PT provided on an inner wall IW of each of the perforated holes FH.

The body BD is made of the anodized film material. An anodized film refers to a film formed by anodizing a base metal. Porous holes 125 refer to holes formed during a metal anodizing process to form an anodized film. For example, when a base metal is an aluminum (Al) or an alloy thereof, and the base metal is anodized, an anodized film made of aluminum oxide (Al₂O₃) is formed on a surface of the base metal. However, the base metal is not limited thereto and includes Ta, Nb, Ti, Zr, Hf, W, and Sb, or alloys thereof.

The anodized film formed as above is perpendicularly divided into a barrier layer 110 without porous holes 125 formed therein and a porous layer 120 with porous holes 125 formed therein.

When the anodized film having the barrier layer and the porous layer is formed on a surface of the base metal, and the base metal is removed, only the anodized film made of aluminum oxide (Al₂O₃) remains. By removing the barrier layer 110 formed during the anodization, the formed anodized film may have a structure in which the porous holes 125 penetrate the film from top to bottom. Alternatively, by the process, the formed anodized film may have a structure in which the barrier layer 110 formed during the anodization remains intact and seals one end of the upper and lower ends of the porous holes 125.

The anodized film has a thermal expansion coefficient of 2 to 3 ppm/° C. For this reason, there is little thermal deformation of the anodized film due to temperature when the anodized film is exposed to a high-temperature environment. Therefore, even when the anodized film structure 100a is used in a high-temperature environment, the anodized film structure 100a may be used without thermal deformation.

During the anodization, the body BD has a larger internal width than the porous holes 125 formed, and also the body BD is provided with perforated holes FH which are formed by penetrating the body BD.

The perforated holes FH are formed through the upper and lower surfaces of the body BD.

The perforated holes FH are formed using an etchant. Referring to FIGS. 4 and 5, a patternable material 21 film is provided on a first surface S1 of the body BD made of the anodized film material. The patternable material 21 may be but is not limited to, a photoresist. At least a portion of the patternable material 21 film is patterned through a patterning process. FIG. 4 shows a patternable material 21 film that has been at least partially patterned through a patterning process. As at least a portion of the patternable material 21 film is patterned, opening regions 22 are formed on the first surface S1 of the body BD.

Then, a process of removing the body BD made of the anodized film material and exposed to the opening regions 22 is performed using the etchant. The body BD made of the anodized film material exposed to the opening regions 22 may be wet etched. Accordingly, holes H (hereinafter, holes H later become perforated holes FH) having a width equal to that of the opening regions 22 are formed. The etchant reacts selectively only with the anodized film. Due to the configuration of the porous holes 125, the perforated holes FH are perforated in a direction parallel to the longitudinal direction of the porous holes 125 and are formed in the form of a perpendicular hole.

Then, the patternable material 21 film is removed by stripping. Accordingly, the perforated holes FH are provided in the body BD.

The perforated holes FH are provided through an etching process using an etchant so that the inner wall IW of each of the perforated holes FH is formed perpendicularly and in a straight line. Because of this, it is possible for a plurality of the perforated holes FH to be formed at a decreased pitch in the body BD.

The cross-sectional shape of the perforated holes FH may be circular. However, the cross-sectional shape of the perforated holes FH is not limited thereto and may be formed in various shapes, including polygons.

The inner wall IW of each of the perforated holes FH is provided with micro-trenches 88 defined by peaks and valleys repeatedly arranged in a circumferential direction of the perforated holes FH.

The micro-trenches 88 are defined by peaks and valleys extending in a longitudinal direction of the perforated holes FH and repeatedly arranged in the circumferential direction of the perforated holes FH. The micro-trenches 88 have a depth in a range of 20 nm to 1 μm and also a width in a range of 20 nm to 1 μm. Herein, when manufacturing the body BD made of the anodized film material, the porous holes 125 are formed, resulting in the formation of the micro-trenches 88. Accordingly, the micro-trenches 88 have a width and depth smaller than or equal to the diameter of the porous holes 125 in the body BD made of the anodized film material. Meanwhile, in the perforated holes FH-forming process in the body BD made of the anodized film material, some of the porous holes 125 are crushed by the etching solution. Thus, at least a portion of the formed micro-trenches 88 may have a depth greater than the diameter of the porous holes 125 formed during the anodization.

The micro-trenches 88 are defined by peaks and valleys repeatedly arranged in a circumferential direction. Therefore, when the inner wall IW of each of the perforated holes FH is not protected by the protective layer PT, particles may be generated on the inner wall IW of each of the perforated holes FH due to friction with the insertion members IS inserted into the perforated holes FH. On the other hand, the anodized film structure 100a of the first embodiment includes protective layer PT on the inner wall IW of each of the perforated holes FH.

The protective layer PT is provided on the inner wall IW of each of the perforated holes FH. The protective layer PT is provided in a thin film form along the inner wall IW of each of the perforated holes FH so as not to seal the perforated holes FH. Specifically, the protective layer PT is provided in a parylene form by depositing parylene through chemical vapor deposition (CVD).

The anodized film structure 100a of the first embodiment includes a protective layer PT on the inner wall IW of each of the perforated holes FH and the entire surface of the body BD. The protective layer PT is evenly formed with a uniform thickness on the entire surface of the body BD and the inner wall IW of the perforated hole FH.

When the protective layer PT is provided on a surface of the body BD and the inner wall IW of each of the perforated holes FH, the micro-trenches 88 are covered by the protective layer PT and are not exposed. In FIGS. 1 and 2, the micro-trenches 88 are indicated by a dotted line. However, the micro-trenches 88 are covered by the protective layer PT formed on a surface of the body BD and are not exposed to the outside.

Referring to FIG. 7, the protective layer PT is formed on the surfaces including a first surface S1 and a second surface S2 of the body BD. The protective layer PT is evenly formed with a uniform thickness on the inner wall IW of each of the perforated holes FH. Accordingly, the protective layer PT is evenly formed with the uniform thickness on a first contact point TP1 formed at the area where the first surface S1 of the body BD meets the upper inner wall IW of each of the perforated holes FH, and a second contact point TP2 formed at the area where the second surface S2 of the body BD meets the lower inner wall IW of each of the perforated holes FH.

In the anodized film structure 100a of the first embodiment, the inner wall IW of each of the perforated holes FH and the surface of the body BD are covered with the protective layer PT. Accordingly, even when the insertion members IS capable of sliding movement are inserted into the perforated holes FH, microparticles made of the anodized film material are not generated.

As shown in FIG. 8, the insertion members IS are installed to be able to perpendicularly slide in the perforated holes FH. The arrow shown on the pictures meaning the insertion members IS in FIG. 8 indicates the direction of sliding movement of the insertion members IS.

When the insertion members IS slide, the outer surfaces of the insertion members IS continuously come into contact with the inner walls IW of the perforated holes FH. At this time, the inner walls IW of the perforated holes FH are covered by the protective layer PT. Accordingly, the body BD does not directly come into contact with the insertion members IS.

The insertion members IS may be electrically conductive contact pins PN provided in the inspection device 1. When an inspection device 1 is a probe card PC, the insertion members IS may be probe pins. When the inspection device 1 is a test socket TS, the insertion members IS may be socket pins. The insertion members are not limited thereto and include any pin used to check whether or not an inspection target 400 is defective by applying electricity.

In the anodized film structure 100a of the first embodiment, protective layer PT is provided on the inner wall IW of each of the perforated holes FH to which external force (friction force) is directly applied by the insertion members IS. The protective layer PT is formed uniformly perpendicular to the inner wall IW formed perpendicularly in a straight shape. The protective layer PT entirely covers the inner wall IW of each of the perforated holes FH.

Unlike the anodized film structure 100a of the first embodiment, when curved and uneven protective layer PT is formed on the inner wall IW of each of the perforated holes FH, the area where the protective layer PT with a relatively thick thickness is formed may rub against the insertion members IS, which may cause particle generation. The perforated holes FH are formed in a compact size. Thus, when the thickness of the protective layer PT is formed unevenly on the inner wall IW of each of the perforated holes FH, the area where the protective layer PT with a relatively thick thickness is formed may rub against the insertion members IS, which may cause particle generation due to friction forces. In particular, when the protective layer PT with a relatively thick thickness is formed at the first tangent point TP1 and second tangent point TP2 where the surface of the body BD and the inner wall IW of each of the perforated holes FH meet, and the insertion members IS slide in the perforated holes FH, friction may occur between the first tangent point TP1 and insertion member IS and between the second tangent point TP2 and the insertion member IS, which may cause particle generation.

However, in the anodized film structure 100a of the first embodiment, protective layer PT with a uniform thickness is formed on the inner wall IW of each of the perforated holes FH and the entire surface of the body BD by depositing parylene. Accordingly, even when the position of the formed protective layer (specifically, the inner wall IW of each of the perforated holes FH and the entire surface of the body BD) is different, the protective layer PT has a uniform thickness. Specifically, the protective layer PT is evenly formed with a uniform thickness on the inner wall IW of each of the perforated holes FH and the surface of the body BD, and even on the first tangent point TP1 and on the second tangent point TP2, which are areas where the inner wall IW of each of the perforated holes FH and the surface of the body BD meet to form a corner. Herein, the first tangent point TP1 is an area where the upper inner wall IW of each of the perforated holes FH and the first surface S1 of the body BD meet to form a corner, and the second tangent point TP2 is an area where the lower inner wall IW of each of the perforated holes FH and the second surface S2 of the body BD meet to form a corner.

In the anodized film structure 100a of the first embodiment, protective layer is formed on the inner wall IW of each of the perforated holes FH, the surface of the body BD, and the first tangent point TP1 and the second tangent point TP2. Thus, when insertion members IS are provided in the perforated holes FH, damage to the inner wall IW of each of the perforated holes FH and particle generation due to friction between the inner wall IW of each of the perforated holes FH and each of the insertion members IS may be prevented.

In addition, the protective layer PT is formed to have a uniform thickness on the inner wall IW of each of the perforated holes FH, the surface of the body BD, and the first tangent point TP1 and the second tangent point TP2. Thus, when insertion members IS are provided in the perforated holes FH, particle generation due to friction between each of the insertion members IS and the inner wall of the protective layer PT at a specific location in the perforated holes FH may be minimized.

The first tangent point TP1 and the second tangent point TP2 are positions where one opening and the other opening of the perforated holes FH are formed, respectively, being located in the periphery thereof. In FIG. 8, as an embodiment, the insertion members IS are shown as being provided in a straight line in the perforated holes FH. However, at least a portion of the insertion members IS may be shifted in the perforated holes FH. Accordingly, at least a portion (specifically, the upper part) of the insertion members IS may be positioned close to the first tangent point TP1. The remaining part (specifically, the lower part) of the insertion members IS may be positioned close to the second tangent point TP2. In the anodized film structure 100a of the first embodiment, protective layer PT with a uniform thickness is formed at the first tangent point TP1 and second tangent point TP2. In other words, the inner wall of the protective layer PT is formed as a flat surface with an overall uniform thickness. As a result, even when the insertion members IS slide in the perforated holes FH, the particle generation may be prevented as each of the insertion members IS rub against the inner wall of the protective layer PT at a specific location.

The protective layer PT is formed by filling the valleys of the micro-trenches 88. Accordingly, the insides of the perforated holes FH are exposed to the protective layer PT, and the protective layer PT is formed as a flat surface. As a result, when the insertion members IS slide in the perforated holes FH, microparticle generation from the protective layer PT is minimized.

The protective layer PT may be formed on the inner wall IW of each of the perforated holes FH and the surface of the body BD through the following steps.

First, a compound material in a powder state is evaporated and converted to be in a gaseous state. The compound material in a powder state is evaporated by heat. The evaporated compound material is converted to be in a gaseous state through the pyrolysis section.

Then, the gaseous compound material is cooled. The gaseous compound material is cooled before the compound material is diffused into the porous chamber. The cooled gas particles polymerize in a vacuum chamber. The polymerization of the cooled gas particles occurs at very low pressure and room temperature below 30° C. Thus, thermal stress is not generated on the inner wall IW of each of the perforated holes FH and the surface of the body BD.

Then, a process of depositing parylene in a film form is performed on the inner wall IW of each of the perforated holes FH and the surface of the body BD. The parylene is deposited evenly with a uniform thickness on the inner wall IW of each of the perforated holes FH and the surface of the body BD. Accordingly, protective layer PT with the uniform thickness is evenly formed not only on the inner wall IW of each of the perforated holes FH and the surface of the body BD but also on the first tangent point TP1 and second tangent point TP2.

### Second Embodiment

Next, a second embodiment according to the present disclosure will be described. However, the embodiment described below will focus on characteristic components compared to the first embodiment. Descriptions of components that are the same or similar to those of the first embodiment are omitted if possible.

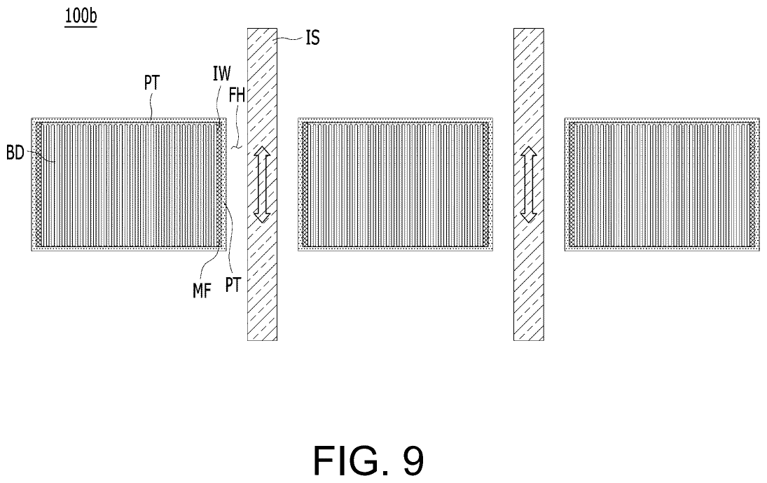

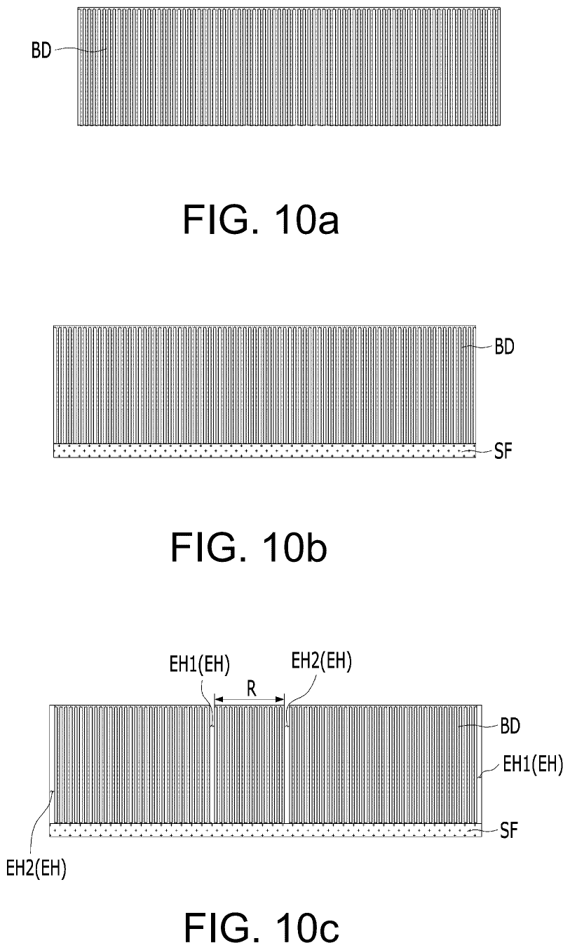

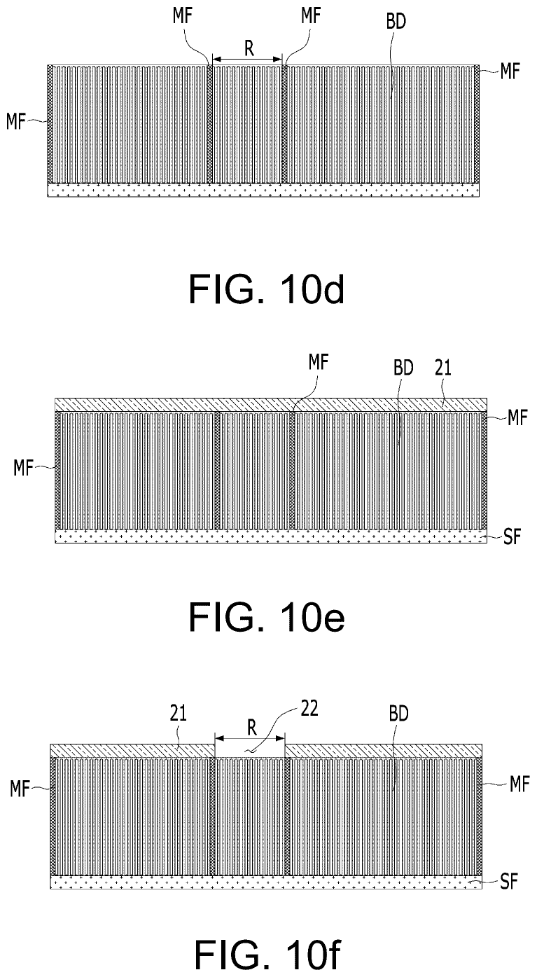

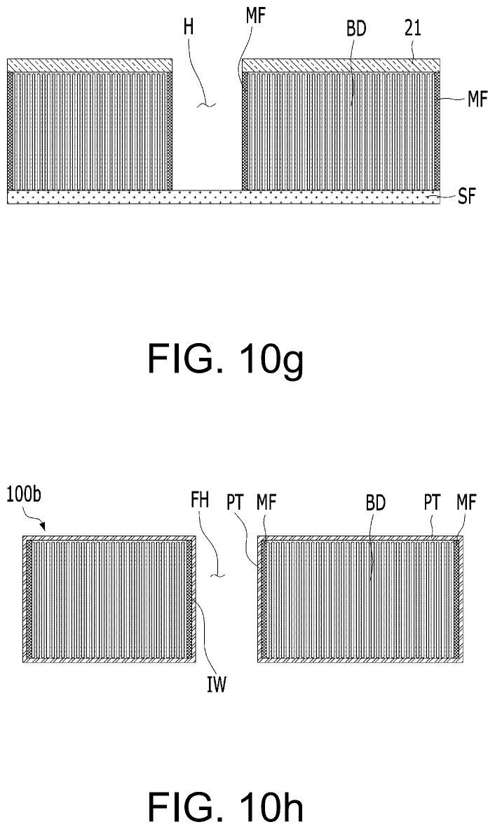

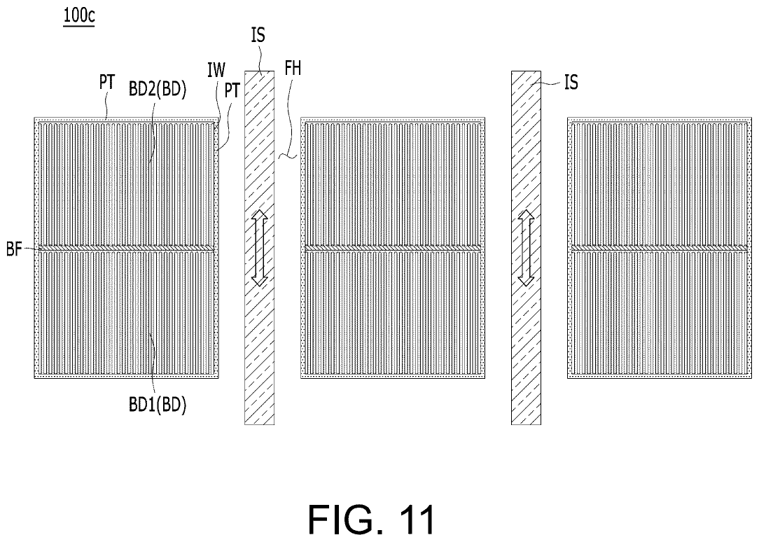

Hereinafter, an anodized film structure according to the second preferred embodiment of the present disclosure (hereinafter referred to as “anodized film structure 100b of the second embodiment”) will be described with reference to FIGS. 9 and 10A to 10H. FIG. 9 shows a state in which insertion members IS are inserted into the anodized film structure 100b according to the second embodiment of the present disclosure. FIGS. 10A to 10H sequentially show a method of manufacturing an anodized film structure 100b according to the second embodiment of the present disclosure.

The anodized film structure 100b of the second embodiment is different from the anodized film structure 100a of the first embodiment in that the anodized film structure 100b of the second embodiment includes a metal layer MF interposed between a protective layer PT and an inner wall IW of each of the perforated holes FH.

The anodized film structure 100b of the second embodiment includes a protective layer PT on a surface of the body BD and an inner wall IW of each of the perforated holes FH. In the anodized film structure 100b of the second embodiment, the metal layer MF is formed on the inner wall IW of each of the perforated holes FH, and then protective layer PT is provided to cover the metal layer ME. The provided metal layer MF is not exposed being interposed between the inner wall IW of each of the perforated holes FH and the protective layer PT.

Referring to FIG. 9, in the anodized film structure 100b of the second embodiment, the inner wall IW of each of the perforated holes FH, the metal layer MF, and the protective layer PT are sequentially positioned from the inside to the outside in the width direction. Accordingly, the protective layer PT is exposed in each of the perforated holes FH.

The metal layer MF is provided on the inner wall of each of the perforated holes FH. The protective layer MF is provided in a thin film form all over the inner wall IW of each of the perforated holes FH so as not to seal the perforated holes FH.

The metal layer MF is formed of at least any one metal selected from the group consisting of rhodium (Rd), platinum (Pt), iridium (Ir), palladium (Pd), nickel (Ni), manganese (Mn), tungsten (W), phosphorus (Ph), titanium (Ti), cobalt (Co), copper (Cu), silver (Ag), gold (Au) or alloys thereof, or palladium-cobalt (PdCo) alloy, palladium-nickel (PdNi) alloy or nickel-phosphorus (NiPh) alloy, nickel-manganese (NiMn), nickel-cobalt (NiCo), or nickel-tungsten (NiW) alloy.

The protective layer PT is formed outside the metal layer MF to cover. The anodized film structure 100b of the second embodiment includes the metal layer MF and protective layer PT, thereby the anodized film structure 100b of the second embodiment includes two layers that serve to protect the inner wall IW of each of the perforated holes FH.

When the metal layer MF is formed of a metal with high wear resistance or hardness, the anodized film structure 100b of the second embodiment primarily protects the inner wall IW of each of the perforated holes FH, and the inner wall IW of each of the perforated holes FH are secondarily protected through the protective layer PT that covers the metal layer ME. In other words, in the anodized film structure 100b of the second embodiment, the metal layer MF is formed on the inner wall IW of each of the perforated holes FH, and the protective layer PT is formed on the inner wall of the metal layer MF so that the inner wall IW of each of the perforated holes FH has a double-protected structure. This may lead to mechanical characteristic improvement of the inner wall IW of each of the perforated holes FH in the anodized film structure 100b of the second embodiment.

A method of manufacturing an anodized film structure 100b of the second embodiment will be described with reference to FIGS. 10A to 10H.

First, referring to FIG. 10A, a body BD made of an anodized film material is provided. Then, referring to FIG. 10B, the body BD is provided on a support layer SF through a sputtering process.

Then, referring to FIG. 10C, through a patterning process using a patternable material 21 film, etching holes EH are formed in at least a portion of the body BD. The etching holes EH have an inner width greater than those of the porous holes 125 and an inner width smaller than those of the perforated holes FH. In FIG. 10C, the patterning process to form the etching holes EH is omitted.

To provide the etching holes EH in the body BD, a patternable material 21 film is provided on the body BD provided on the support layer SF, and at least a portion of the film is patterned to form opening regions 22. Next, the body BD made of the anodized film material and exposed to the opening regions 22 is removed using an etchant. Then, the patternable material 21 film in the corresponding regions is removed.

A plurality of the etching holes EH is provided in at least a portion of the body BD at a predetermined distance apart. Preferably, a plurality of first etching holes EH1 and second etching holes EH2 in a pair is provided apart at a predetermined distance. The spacing distance R between the first etching holes EH1 and the second etching holes EH2 has a dimension larger than that of the insertion members IS in the width direction. FIG. 10C shows the first etching holes EH1 and the second etching holes EH2 in a pair spaced apart by the spacing distance R.

Then, referring to FIG. 10D, metal layers MF are formed with the growth of the etching holes EH through an electroplating process.

Afterward, steps are performed to form the perforated holes FH. First, referring to FIG. 10E, the patternable material 21 film is provided on the upper surface (first surface S1) of the body BD provided with multiple metal layers MF therein. Next, referring to FIG. 10F, at least a portion of the patternable material 21 film is patterned to form opening regions 22. The opening regions 22 are formed corresponding to the at least a portion of the body BD, the portion being located at the spacing distance R between the first etching holes EH1 and the second etching holes EH2. Accordingly, the opening regions 22 have a width equal to that of the spacing distance R between the first etching holes EH1 and the second etching holes EH2. The opening regions 22 allow the at least a portion of the body BD, the portion being located at the spacing distance R between the first etching holes EH1 and the second etching holes EH2 in a pair to be exposed. The patternable material 21 film is provided to cover the remaining portion of the body BD and the upper surface of the metal layers MF except for the at least a portion of the body BD at which the spacing distance R is located.

Then, referring to FIG. 10G, the at least a portion of the body BD exposed to the opening regions 22 are etched using an etchant to form holes H. The etchant reacts only with the anodized film material constituting the body BD. Accordingly, the metal layers MF are maintained on the inner walls of the holes H (hereinafter, holes H later become perforated holes FH) due to etching. Then, the patternable material 21 film and the support layer SF are removed.

Afterward, referring to 101, a process of forming a protective layer PT is performed on an inner wall of each of the metal layers MF which is formed on the inner wall IW of each of the perforated holes FH, and a surface of the body BD. The protective layer PT is formed by depositing parylene. Since this has been described in detail in the section of the anodized film structure 100a of the first embodiment, a detailed description will be omitted.

The anodized film structure 100b of the second embodiment entirely covers a surface of the body BD and an inner wall IW of each of the perforated holes FH by the protective layer PT, but each of the metal layers MF is interposed between the inner wall IW of each of the perforated holes FH and the protective layer PT so as not to expose to inner wall IW of each of the perforated holes FH. In the anodized film structure 100b of the second embodiment, the inner wall IW of each of the perforated holes FH is double protected by each of the metal layers MF and the protective layer PT. Therefore, durability deterioration due to friction between the inner wall IW of each of the perforated holes FH and each of the insertion members IS may be more effectively solved.

### Third Embodiment

Next, a third embodiment according to the present disclosure will be described. However, the embodiment described below will focus on characteristic components compared to the first embodiment. Descriptions of components that are the same or similar to those of the first embodiment are omitted if possible.

Hereinafter, an anodized film structure according to the third preferred embodiment of the present disclosure (hereinafter referred to as “anodized film structure 100c of the third embodiment”) will be described with reference to FIG. 11. FIG. 11 shows a diagram illustrating a state in which the insertion members IS are inserted into the anodized film structure 100c of the third embodiment.

The anodized film structure 100c of the third embodiment is different from the anodized film structure 100a of the first embodiment in that the anodized film structure 100c of the third embodiment includes a plurality of bodies BD made of an anodized film material and joined by a bonding layer BF therebetween.

In the anodized film structure 100c of the second embodiment, protective layers PT on inner walls IW of the perforated holes FH in at least two bodies BD joined by a bonding layer BF. The protective layers PT are also provided on the surfaces of the bodies BD joined by the bonding layer BF.

In FIG. 11, the anodized film structure 100c of the third embodiment is shown as a structure of two bodies BD joined, but the number of the bodies BD constituting the anodized film structure 100c of the third embodiment is not limited thereto. As an example, the anodized film structure 100c of the third embodiment may have three bodies BD, four bodies BD, or more bodies BD joined by the bonding layer BF.

The bonding layer BF may be made of a photoresist or a thermosetting resin. When the bonding layer BF is made of the thermosetting resin, the thermosetting resin may be polyimide resin, polyquinoline resin, polyamidoimide resin, epoxy resin, polyphenylene ether resin, and fluororesin.

The anodic oxide film structure 100c of the third embodiment may be manufactured by forming perforated holes FH in each body BD through a patterning process using a patternable material 21 film, and then bringing the positions of the perforated holes FH in each body BD to correspond to each other and the bodies BD to be joined by the bonding layers BF. At this time, the bonding layer BF may be made of a material with a bonding function, and the bonding layer BF may be provided with opened portions corresponding to the perforated holes FH.

Unlike this, the anodized film structure 100c of the third embodiment may include a bonding layer BF of a photoresist on one surface of at least one body BD.

Hereinafter, based on the longitudinal direction of FIG. 11, one body BD provided at the bottom will be referred to as a first body BD1, and another body BD provided at the top of the first body BD1 will be referred to as a second body BD2.

When the bonding layer BF is made of the photoresist, the bonding layer BF may be provided on at least one of the first body BD1 and the second body BD2. As an example, the first body BD1 may be provided with a bonding layer BF. In this case, the bonding layer BF functions as the patternable material 21 film, so at least a portion thereof is patterned to form opening regions 22. The first body BD1 is provided with perforated holes FH by performing an etching process using the opening regions 22 to form holes (hereinafter, holes H later become perforated holes FH). When the anodized film structure 100c of the third embodiment has the bonding layer BF made of the photoresist, in the process of providing the perforated holes FH, at least portions of the first body BD1 in the opening regions 22 are removed. Then, without removing the bonding layer BF provided on one surface of the first body BD1, the second body BD2 may be stacked with the bonding layer BF. In this case, the bonding layer BF may perform a space-providing function to form the perforated holes FH and a bonding function.

Meanwhile, the second body BD2 joined onto an upper surface of the first body BD1 may be a circular body BD made of the anodized film material without perforated holes FH formed. The second body BD2 is joined onto the upper surface of the first body BD1 through a bonding layer BF in a circular shape, and then at least portions of the second body BD2 exposed through the perforated holes FH of the first body BD1 may be etched through an etching process. As a result, the second body BD2 may be provided with perforated holes FH which communicate with the perforated holes FH of the first body BD1 at their corresponding positions.

Unlike this, the second body BD2 may be joined on the upper surface of the first body BD1 provided with perforated holes FH in advance through a patterning process using the patternable material 21 film.

The method of forming the perforated holes FH in the first body BD1 and second body BD2, respectively, and joining the bodies is not limited to the method described above.

In the anodized film structure 100c of the third embodiment, protective layers PT are provided on the inner walls IW of the perforated holes FH and the surfaces of the stacked bodies BD (specifically, the surfaces of the first body BD1 and second body BD2 exposed to the outside) by bringing the bodies BD joined by a bonding layer BF and then depositing parylene.

The anodized film structure 100c of the third embodiment may have excellent overall mechanical strength by having a structure in which a plurality of the bodies BD is stacked and joined. In addition, in the anodized film structure 100c of the third embodiment, protective layers PT are provided on the inner walls IW of the perforated holes FH, and the surfaces of the bodies BD in a structure of a plurality of the bodies are joined, thereby the inner walls IW of the perforated holes FH may be protected from friction with the insertion members IS, and durability may be improved.

Meanwhile, in the anodized film structure 100c of the third embodiment, metal layers MF may be interposed between the inner walls IW of the perforated holes FH and the protective layers PT in a structure of a plurality of bodies BD stacked.

In this case, a bonding layer BF made of the photoresist may be provided on at least one surface (specifically, the first surface S1) of the first body BD1 and second body BD2.

As an example, the bonding layer BF may be provided on the first surface S1 of the first body BD1. Next, a patterning process may be performed on the bonding layer BF to form opening regions. Then, an etching process may be performed on at least portions of the first body BD1 exposed through the opening regions 22. Due to this, a plurality of first etching holes EH1 and second etching holes EH2 in a pair may be formed in the first body BD1. The process of performing a plurality of the first etching holes EH1 and second etching holes EH2 in a pair is the same as the process of forming the first etching holes EH1 and second etching holes EH2 of the anodized film structure 100b of the second embodiment. Accordingly, a detailed description will be omitted.

Afterward, the circular second body BD2 may be joined on the first body BD1 by the bonding layer BF. Afterward, an etching process may be performed on at least portions of the second body BD2 exposed in the first etching holes EH1 and second etching holes EH2. Due to this, the first etching holes EH1 and second etching holes EH2 of the second body may be provided, communicating with the first etching holes EH1 and second etching holes EH2 of the first body BD1 at their corresponding positions, respectively.

Afterward, an electroplating process may be performed on the etching holes EH including the first etching holes EH1 and second etching holes EH2 of the respective first body BD1 and second body BD2. Through the electroplating process, metal layers MF may be provided in the etching holes EH.

Afterward, the patternable material 21 film may be provided on at least one of the first surface S1 of the second body BD2 and the second surface S2 of the first body BD1, and opening regions 22 may be provided through a patterning process.

As an example, the patternable material 21 film may be provided on the first surface S1 of the second body BD2, and opening regions 22 may be formed. At this time, the patternable material 21, a film of which has opening regions 22 formed therein may cover the upper surface of the metal layers MF of the second body BD2 and the upper surface (first surface S1) of the remaining part of the second body BD2 except for the at least portion of the second body BD2 exposed through the opening regions 22.

Afterward, through the etching process, at least a portion of the second body BD2 exposed to the opening regions 22 may be etched to form perforated holes FH in the second body BD2.

Afterward, a process of removing at least portions of the provided bonding layer BF corresponding to the perforated holes FH of the second body BD2 may be performed. When the bonding layer BF is made of the photoresist, the at least portions of the bonding layer BF may be removed through a patterning process.

Afterward, at least a portion of the first body BD1 exposed to the perforated holes FH of the second body BD2 may be removed through an etching process to form the perforated holes FH in the first body BD1.

The patternable material 21 film provided on the first surface S1 of the second body BD2 may be removed after forming the perforated holes FH in the first body BD1 and second body BD2. The patternable material 21 film may be continuously removed after forming the perforated holes FH in the second body BD2.

Accordingly, the metal layers MF may be formed on the inner walls IW of the perforated holes FH, which are formed in a structure of the first body BD1 and the second body BD2 stacked.

Afterward, a process of providing protective layers PT on the inner walls of the metal layers MF, the surface of the first body BD1, and the surface of the second body BD2 may be performed.

In the anodized film structure 100c of the third embodiment, the first body BD1 and the second body BD2 are stacked joined by a bonding layer BF. In addition, in the anodized film structure 100c of the third embodiment, metal layers MF are interposed between the inner walls IW of the perforated holes FH and the protective layers PT. Thus, the anodized film structure 100c of the third embodiment may be excellent in mechanical strength.

A method of providing the anodized film structure 100c of the third embodiment, which has a structure in which metal layers MF are interposed between the inner walls IW of the perforated holes FH and the protective layers PT in a structure of the first body BD1 and the second body BD2 joined, is not limited to the method described above.

### Fourth Embodiment

Next, a fourth embodiment according to the present disclosure will be described. However, the embodiment described below will focus on characteristic components compared to the first embodiment. Descriptions of components that are the same or similar to those of the first embodiment are omitted if possible.

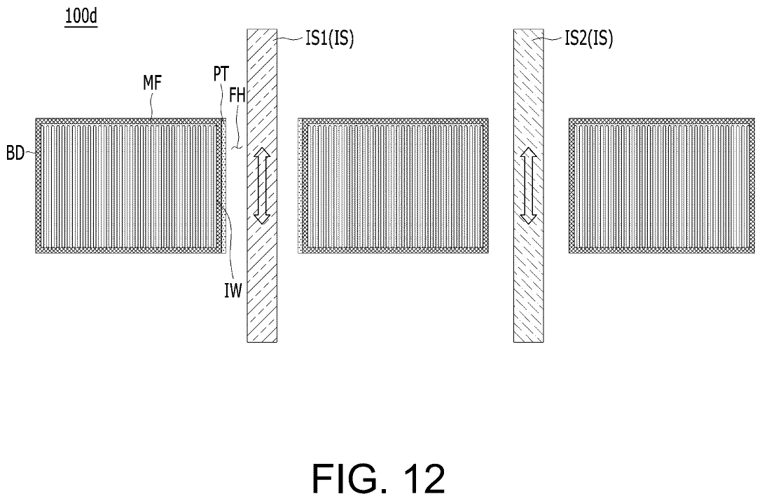

Hereinafter, an anodized film structure according to the fourth preferred embodiment of the present disclosure (hereinafter referred to as “anodized film structure 100d of the fourth embodiment”) will be described with reference to FIG. 12. FIG. 12 shows a diagram illustrating a state in which the insertion members IS are inserted into the anodized film structure 100d of the fourth embodiment. At least some of the plurality of insertion members IS inserted into the anodized film structure 100d of the fourth embodiment are signal pins, and the remaining insertion members IS are ground pins.

The anodized film structure 100d of the fourth embodiment is different from that of the first embodiment in that the anodized film structure 100d of the fourth embodiment includes a metal layer MF provided on a surface of the body BD and between a protective layer PT and an inner wall IW of each of perforated holes FH.

Referring to FIG. 12, the anodized film structure 100d of the fourth embodiment includes the metal layer MF on the surface of the body BD and the inner wall IW of each of the perforated holes FH.

In the anodized film structure 100d of the fourth embodiment, protective layer PT is provided for at least some perforated holes among the plurality of perforated holes FH. The some perforated holes FH have a respective metal layer MF formed on the inner wall IW thereof. The protective layer PT covers the metal layer MF, being formed on the inner wall of the metal layer MF. The metal layer MF is not exposed in the perforated holes FH by the protective layer PT.

Meanwhile, among the plurality of perforated holes FH, the remaining ones have only the metal layer MF on the inner wall thereof, and the metal layer MF thereof is exposed.

The anodized film structure 100d of the fourth embodiment may include the metal layer MF on the surface of the body BD and the inner wall IW of each of the perforated holes FH through an electroplating process. The metal layer MF formed on the surface of the body BD is provided by growing metal on the surface of the body BD through electric current. The metal layer MF formed on the inner wall of each of the perforated holes FH are provided in the same method as that in the second embodiment of the anodized film structure 100b, which is forming a first etching hole EH1 and a second etching hole EH2, and then forming a metal layer MF in the first etching hole EH1 and second etching hole EH.

With the metal layer MF formed on the surface of the body BD and the inner wall IW of each of the perforated holes FH, the body BD includes the protective layer PT formed on the inner wall IW of each of at least some perforated holes among the plurality of the perforated holes FH through a parylene deposition method.

In FIG. 12, two insertion members IS are shown, including a first insertion member IS1 and a second insertion member IS2. Among the first insertion member IS1 and the second insertion member IS2, at least one of the insertion members IS is a signal pin and the other is a ground pin. As an example, the first insertion member IS1 may be a signal pin, and the second insertion member IS2 may be a ground pin.

The first insertion member IS1 is provided in a perforated hole FH, the inner wall of which is covered with a metal layer MF protected by a protective layer PT, among a plurality of the perforated holes FH. The first insertion member IS1 is required to maintain an insulated state while being inserted into the perforated hole FH to receive and transmit signals. The first insertion member IS1 maintains its insulated state by being inserted into the perforated hole FH with the metal layer MF not exposed thereon since the metal layer is covered by the protective layer PT. By being formed on the inner wall of the metal layer MF and exposed in the perforated hole FH, the protective layer PT may function to block the electrical connection between the metal layer MF and the first insertion member IS1.

The second insertion member IS2 is provided in a perforated hole FH, the inner wall of which is covered with a metal layer MF exposed, among a plurality of the perforated holes FH. The second insertion member IS2 performs a grounding function. Thus, it is okay for the second insertion member IS2 to partially come into contact with the metal layer MF and be electrically connected while sliding in the perforated hole FH. In other words, it does not matter if the metal layer MF is exposed in the perforated hole FH where the second insertion member IS2 is inserted. In addition, the second insertion member IS2 inserted into the anodized film structure 100d of the fourth embodiment in multiple pieces may be electrically connected to each other.

The protective layer MF covers and protects the inner wall IW of each of the perforated holes FH. Thus, when the second insertion member IS2 slides, even when at least a portion of the second insertion member IS2 comes into contact with the metal layer MF, the inner wall IW of each of the perforated holes FH for the second insertion member IS2 is protected.

The anodized film structure 100d of the fourth embodiment includes a plurality of the perforated holes FH, among the plurality of the perforated holes FH, at least some perforated holes FH have a metal layer MF covered, and the remaining ones have a metal layer MF exposed. Accordingly, the first insertion member IS1 and the second insertion member IS2 inserted into the anodized film structure 100d of the fourth embodiment are electrically separated.

In the anodized film structure 100d of the fourth embodiment, the metal layer MF occupies a relatively large area out of the total area of the anodized film structure 100d by forming the metal layer MF on the entire surface of the body BD exposed to the outside and the inner wall IW of each of the perforated holes FH. The anodized film structure 100d of the fourth embodiment may significantly reduce interference and noise of signals received and transmitted by the first insertion member IS1 through the metal layer MF. For this reason, the anodized film structure 100d of the fourth embodiment may be more advantageous when used to inspect the high-frequency characteristics of an inspection target (for example, semiconductor wafer or semiconductor package) with the first insertion member IS1 and the second insertion member IS2 inserted.

### Inspection Device According to Preferred Embodiment of Present Disclosure

An inspection device 1 according to a preferred embodiment of the present disclosure includes bodies BD made of an anodized film material, perforated holes FH provided in the bodies BD, anodized film structures 100a, 100b, 100c, and 100d including protective layers PT provided on the inner walls of the perforated holes FH, electrically conductive contact pins PN inserted into the perforated holes FH, and a circuit unit CU connected to the electrically conductive contact pins PN.

The inspection device 1 according to another preferred embodiment of the present disclosure may be an inspection device used in a semiconductor manufacturing process. The inspection device 1 may be, for example, a probe card PC or a test socket TS. The electrically conductive contact pins PN may be probe pins provided on the probe card PC to inspect a semiconductor chip. The electrically conductive contact pins PN may be socket pins provided in a test socket TS to inspect a packaged semiconductor package. The inspection device 1 according to a further preferred embodiment of the present disclosure is not limited thereto and includes any inspection device to check whether or not an inspection target is defective by applying electricity.

When the inspection device 1 according to a yet further preferred embodiment of the present disclosure is the probe card PC, the inspection target 400 may be a semiconductor wafer W. When the inspection device 1 is the test socket TS, the inspection target 400 may be connection terminals 410 provided on the bottom of the semiconductor package PK.

The anodized film structures 100a, 100b, 100c, and 100d constituting the inspection device 1 according to a still yet further preferred embodiment of the present disclosure may be at least one of the anodized film structures 100a, 100b, 100c, and 100d of the first to fourth preferred embodiments of the present disclosure.

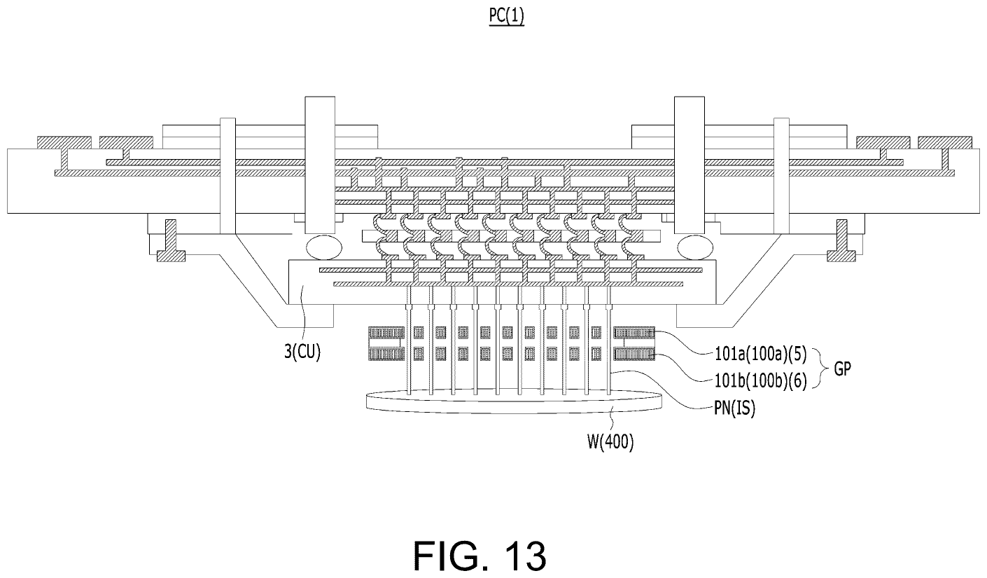

FIG. 13 shows a diagram illustrating that an inspection device 1 is a probe card according to a still yet further preferred embodiment of the present disclosure. The probe card includes at least one of the anodized film structures 100a, 100b, 100c, and 100d of the first to fourth embodiments functioning as guide plates GP, spatial converter 3 functioning as a circuit unit CU, electrically conductive contact pins PN, and a circuit unit CU. In FIG. 13, as an example, the anodized film structure 100a of the first embodiment constituting a guide plate GP is shown.

The guide plates GP include an upper guide plate 5 and a lower guide plate 6. The anodized film structure 100a of the first embodiment constitutes the upper guide plate 5 and the lower guide plate 6, respectively. Hereinafter, the anodized film structure 100a of the first embodiment constituting the upper guide plate 5 will be referred to as an upper anodized film structure 101a. The anodized film structure 100a of the first embodiment constituting the lower guide plate 6 is referred to as a lower anodized film structure 101b.

The upper anodized film structure 101a and lower anodized film structure 101b are fixedly installed through spacers. In the upper anodized film structure 101a and lower anodized film structure 101b), the electrically conductive contact pins PN are provided in the perforated holes FH. In this case, the protective layers PT are formed on the inner walls IW of the perforated holes FH.

Electrical characteristic testing of semiconductor devices is performed by approaching a semiconductor wafer W to the probe card equipped with a plurality of electrically conductive contact pins PN and bringing each of the electrically conductive contact pins PN into contact with the corresponding electrode pads on the semiconductor wafer W.

Next, an overdriving process is performed to further raise the wafer W to a predetermined height toward the probe card.

However, during the overdriving process, the electrically conductive contact pins PN may come into contact with the inner walls IW of the perforated holes FH, causing damage to the inner walls IW of the perforated holes FH and finally the generation of particles.

However, the inspection device 1 according to a still yet further preferred embodiment of the present disclosure is provided with any of the anodized film structures 100a, 100b, 100c, and 100d to protect the inner walls IW of the perforated holes FH through protective layers PT. Accordingly, durability deterioration caused by damage to the inner walls IW of the perforated holes FH may be solved. In addition, the protective layers PT are formed to have a uniform thickness throughout the inner walls of the perforated holes FH so that particle generation may be minimized.

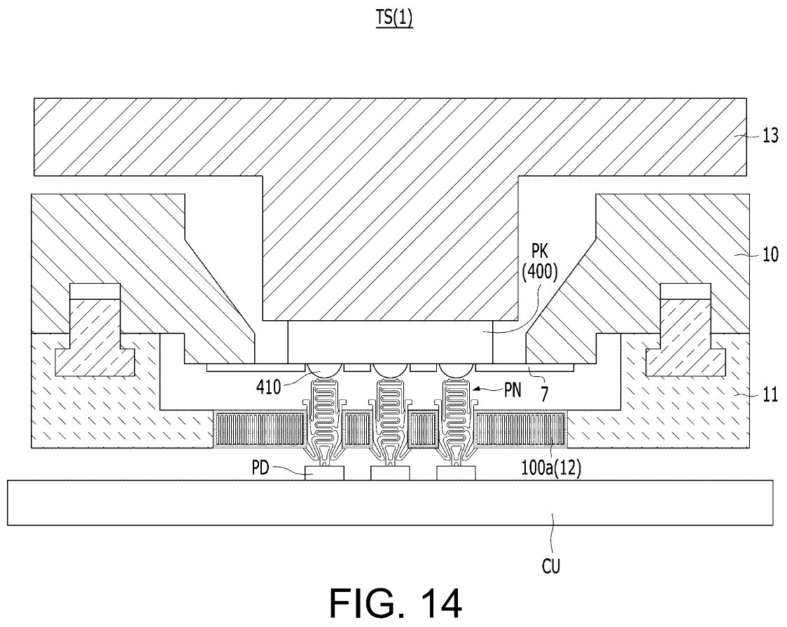

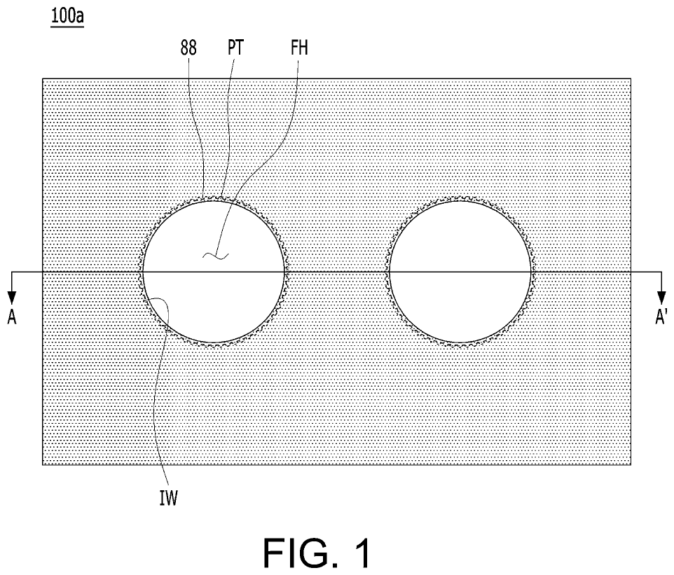

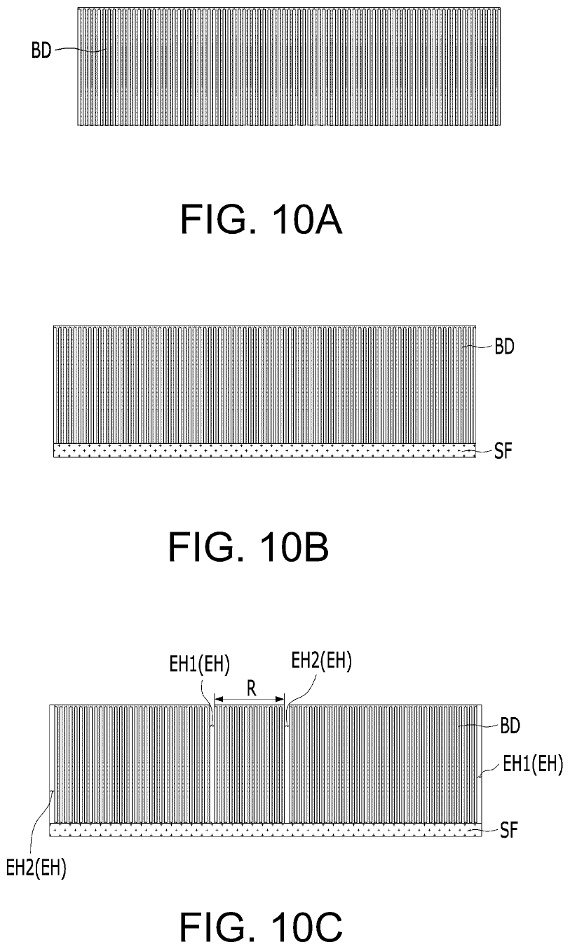

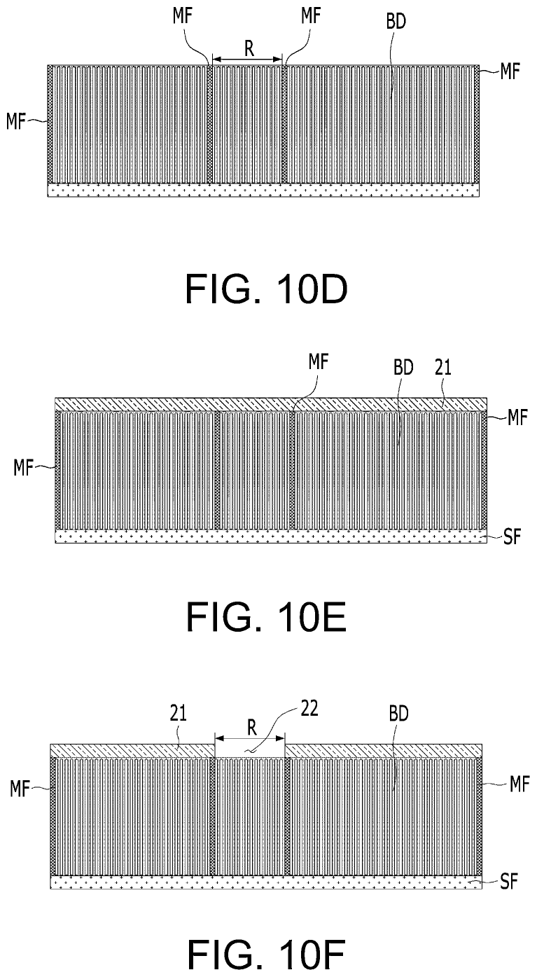

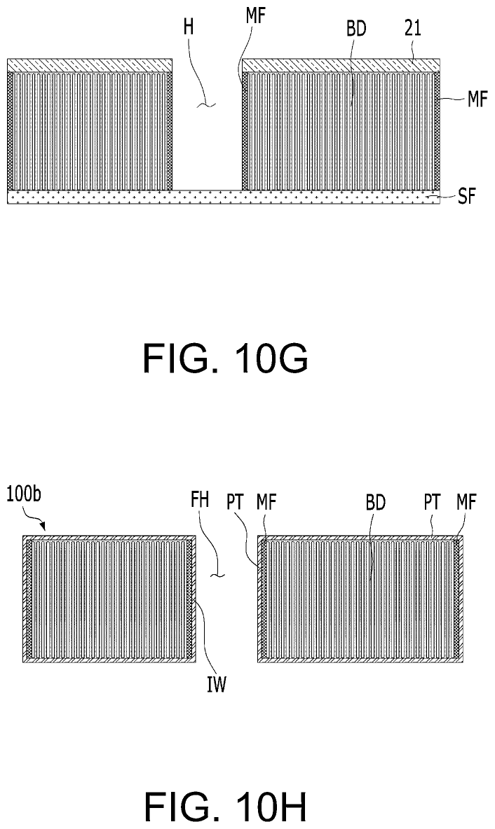

FIG. 14 is a diagram showing that a test device 1 is a test socket TS according to a still yet further preferred embodiment of the present disclosure. The test socket TS includes insert bodies 10, guides 11, installation members 12 made from at least one of the anodized film structures 100a, 100b, 100c, and 100d of the first to fourth embodiments, electrically conductive contact pins PN and a pusher 13, and a circuit unit CU. In FIG. 14, as an example, the anodized film structure 100a of the first embodiment constituting the installation member 12 is shown.

The insert bodies 10 accommodate the semiconductor package, which is the inspection target 400, ensuring that the inspection target 400 is stabilized and the testing may be conducted reliably.

The guides 11 serve to guide the installation of the installation members 12. Accordingly, the installation of the anodized film structure 100a of the first embodiment is guided.

The anodized film structure 100a of the first embodiment, which functions as the installation members 12, is fixedly installed on the mounting portion of the guides 11, and a plurality of the electrically conductive contact pins PN is installed.

Guides films 7 with holes are installed on the bottom of the insert bodies 10 to guide the connection terminals 410 of the inspection target 400. The guide films 7 are interposed between the inspection target 400 and the electrically conductive contact pins PN.

When the inspection target 400 is inspected, the guide films 7 guide accurate contact positions by allowing the connection terminals 410 of the inspection target 400 to be inserted into the holes provided in the guide films 7.

The pusher 13 serves to press the inspection target 400 seated in the receiving portion of the insert bodies 10 at a constant pressure. The inspection target 400 pressed by the pusher 13 is electrically connected to the pads PD of the circuit unit CU through the electrically conductive contact pins PN installed on the anodized film structure 100a of the first embodiment.

In the inspection device 1 according to a still yet further preferred embodiment of the present disclosure, protective layers PT are provided on the inner walls IW of the perforated holes FH of the anodized film structures 100a, 100b, 100c, and 100d that function as the installation members 12. In the process where the inspection target 400 pressed by the pusher 13 is electrically connected to the pads PD through the electrically conductive contact pins PN, the protective layers PT serve as a protector so that the electrically conductive contact pins PN do not rub against the inner walls IW of the perforated holes FH. The inner walls IW of the perforated holes FH are protected by the protective layers PT, so damage thereto may be prevented. In addition, the protective layers PT are formed with an overall uniform thickness on the inner walls IW of the perforated holes FH and may minimize particle generation caused by friction between the inner walls and the electrically conductive contact pins PN.

As described above, the present disclosure has been described with reference to preferred embodiments. However, those skilled in the art may carry out various modifications or changes to the present disclosure without departing from the spirit and scope of the present disclosure as set forth in the patent claims below.

1. An anodized film structure, comprising:
a body made of an anodized film material;
perforated holes provided in the body; and
a protective layer provided on an inner wall of each of the perforated holes.

2. The anodized film structure of claim 1, wherein the protective layer is provided on the inner wall of each of the perforated holes and a surface of the body, and
the protective layer is evenly formed with a uniform thickness on the inner wall of each of the perforated holes and the surface of the body.

3. The anodized film structure of claim 1, wherein the protective layer is in a parylene form.

4. The anodized film structure of claim 1, wherein a metal layer is interposed between the inner wall of each of the perforated holes and the protective layer.

5. The anodized film structure of claim 1, wherein a plurality of the bodies is provided and stacked with a bonding layer provided between each of the bodies.

6. The anodized film structure of claim 1, wherein a metal layer is provided on a surface of the body, and
the metal layer is interposed between the protective layer and the inner wall of each of the perforated holes.

7. The anodized film structure of claim 6, wherein a plurality of the perforated holes is provided, and
in at least some of the plurality of the perforated holes, the protective layer covers the metal layer so that the metal layer is not exposed, but in the remaining perforated holes, the metal layer is exposed.

8. The anodized film structure of claim 1, wherein the inner wall of the perforated holes is provided with micro-trenches defined by peaks and valleys repeatedly arranged in a circumferential direction of the perforated hole, and
the protective layer entirely covers the micro-trenches.

9. An inspection device comprising:
an anodized film structure comprising bodies made of an anodized film material, perforated holes provided in the bodies, and protective layers provided on inner walls of the perforated holes;
electrically conductive contact pins inserted into the perforated holes; and
a circuit unit connected to the electrically conductive contact pins.
